(19) United States
(12) Patent Application Publication
(10) Pub. No.: US 2006/0125102 A1
(43) Pub. Date: Jun. 15, 2006

(54) Back end of line integration scheme

(76) Inventors: Zhen-Cheng Wu, Hsin-Chu (TW); Ying-Tsung Chen, Chiayi (TW); Pi-Tsung Chen, Tainan County (TW); Yung-Cheng Lu, Taipei (TW)

Correspondence Address: SLATER & MATSIL, L.L.P., 17950 PRESTON ROAD, SUITE 1000, DALLAS, TX, 75252, US

(21) Appl. No.: 11/012,406

(22) Filed: Dec. 15, 2004

(51) Int. Cl. H01L 23/52; H01L 21/4763

(52) U.S. Cl. 257/759; 257/760; 438/623; 438/624

(57) ABSTRACT

A semiconductor structure comprises: a first inter-layer dielectric (ILD) over a substrate; a first metal layer; a plurality of second ILDs over the first ILD; and a plurality of second metal layers, each of the second metal layers is over one of the second ILDs. The first ILD is not cured. It has a k value of between about 2.5 and about 3.0, a pore size of smaller than about 10 Å, and a hardness of greater than about 1.5 Gpa. The second ILDs are cured therefore having lower k values of smaller than about 2.5, pore sizes of greater than about 10 Å, and hardness of smaller than about 1.5 Gpa. The semiconductor structure has reduced plasma charge damage from plasma curing.

### TECHNICAL FIELD

This invention relates generally to semiconductor process, specifically to back-end-of-the-line-process, and more specifically to the formation of inter-level dielectrics.

### BACKGROUND

As the semiconductor industry introduces new generations of integrated circuits (IC's) having higher performance and greater functionality, the density of the elements that form those IC's is increased, while the dimensions, sizes and spacing between the individual components or elements are reduced. While in the past such reductions were limited only by the ability to define the structures photo-lithographically, device geometries having smaller dimensions created new limiting factors. For example, for any two adjacent conductive paths, as the distance between the conductors decreases, the resulting capacitance (a function of the dielectric constant (k) of the insulating material divided by the distance between conductive paths) increases. This increased capacitance results in increased capacitive coupling between the conductors, increased power consumption, an increase in the resistive-capacitive (RC) time constant. Therefore, the continual improvement in semiconductor IC performance and functionality is dependent upon developing materials that form a dielectric film with a lower dielectric constant (k) than that of the most commonly used material, silicon oxide, thus resulting in reduced capacitance. As the dimensions of these devices get smaller and smaller significant reductions in capacitance into the so-called “ultra low-k” regime (e.g., k<2.5) is required.

New materials with low dielectric constants (known in the art as “low-k dielectrics”) are being investigated for their use as insulators in semiconductor chip designs. A low dielectric constant material aids in enabling further reduction in the integrated circuit feature dimensions. In conventional IC processing, SiO₂ is used as a basis for the dielectric material resulting in a dielectric constant of about 3.9. Moreover, advanced low-k dielectric materials have dielectric constants below about 2.8. The substance with the lowest dielectric constant is air (k=1.0). Therefore, porous dielectrics are very promising candidates since they have the potential to provide very low dielectric constants.

Low-k dielectric materials produced by spin-on or chemical vapor deposition processes typically require a curing process subsequent to the deposition in order to further lower k value into ultra-low k region, wherein the k value is smaller than about 2.5. Typical curing methods include thermal curing, plasma treating, and ultra violet (UV) curing. Among the three methods, plasma and UV curing are performed at substantially shorter times or at lower temperatures, eliminating the need for prior furnace curing and therefore reducing the total thermal budget. Plasma curing can increase the mechanical strength of porous low-k dielectrics by providing additional cross-linking of the film.

However, porous films are mechanically weak by nature. Weak films would fail in the chemical mechanical polishing (CMP) process employed to planarize the wafer surface during chip manufacturing. The mechanical properties of a porous film are functions of the porosity of the film. Naturally, higher porosity results in lower dielectric constant but poorer mechanical properties. Typical ultra low-k dielectrics have k values of smaller than about 2.5, pore sizes of greater than about 10 Å and weak mechanical hardness of smaller than about 1.5 Gpa.

Plasma curing also causes severe plasma induced damage to front-end-of-the-line (FEOL) devices. After curing, the gate leakage current is significantly increased. Thus a method that preserves the benefit of curing while reducing device performance degradation is needed.

### SUMMARY OF THE INVENTION

The preferred embodiment of the present invention presents a back-end-of-the-line process. A semiconductor structure having reduced plasma charge damage is formed.

In accordance with one aspect of the present invention, the semiconductor structure comprises: a first inter-layer dielectric (ILD) over a substrate; a first metal layer over the first ILD; a plurality of second ILDs over the first metal layer; and a plurality of second metal layers, each of the second metal layers being over one of the second ILDs. The first ILD is not cured, and therefore, has a k value of between about 2.5 and about 3.0, a pore size of smaller than about 10 Å, and a hardness of greater than about 1.5 Gpa. The second ILDs are preferably cured and, therefore, are more porous. They typically have lower k values of smaller than about 2.5, pore sizes of greater than about 10 Å, and hardness of smaller than about 1.5 Gpa.

In the preferred embodiment, the lowest level ILD is not cured while higher-level ILDs are cured. The semiconductor structure has a better mechanical strength with a combined structure of cured and uncured ILDs. The MOS devices' gate leakage current is reduced significantly. The process if fully compatible with current low-k/ultra low-k processes. There is no extra cost involved. Existing tools can be used.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross sectional view of a semiconductor structure having an inter-layer dielectric (ILD), a metal layer and an etch stop layer (ESL) over a substrate;

FIG. 2 illustrates a cross sectional view of a second ILD, a second metal layer and a second ESL over the semiconductor structure in FIG. 1;

FIG. 3 illustrates a cross sectional view of a semiconductor structure having multiple layers of ILDs, metal layers and ESLs on a substrate; and

FIG. 4 illustrates gate leakage currents as functions of yield.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In a semiconductor integrated circuit manufacturing process, semiconductor devices are formed in/on a substrate. Metal lines are used to interconnect devices. Metal lines may be formed in different layers and separated by inter-layer dielectrics (ILD), also called inter-metal dielectrics (IMD). Semiconductor devices of such type may comprise eight or more levels of metal layers to satisfy device geometry and micro miniaturization requirements. Metal layers are referred as M1 through Mn with M1 being the lowest (closest to the substrate), assuming there are n metal levels. FIGS. 1 through 3 illustrate cross-sectional views of intermediate stages in the manufacture of multiple metal layers separated by ILDs.

FIG. 1 illustrates a substrate 2 and an ILD 4. Substrate 2 typically has devices formed (not shown) in/on it. In the preferred embodiment, ILD 4 is a dielectric having a dielectric constant (k value) of between about 2.5 and about 3.0, a pore size of smaller than about 10 Å, and a hardness of greater than about 1.5 Gpa. The material of ILD 4 may comprise materials such as SiCo₂H, black diamond, coral, or their combinations. The ILD 4 is preferably formed by spin-on, chemical vapor deposition (CVD), plasma enhanced CVD (PECVD), atomic layer deposition (ALD), sub-atmospheric CVD (SACVD), low pressure CVD (LPCVD), or other well-known deposition techniques. In an exemplary setting, a depositing tool named AMAT′ Producer is used, and deposition is performed using precursors (CH₃)₃SiH (also known as 3MS or trimethylsilane) and oxygen. The deposition is conducted at an elevated temperature of about 350° C. The ILD 4 formed using the exemplary setting has a k value of about 3.0, a pore size of smaller than about 10 Å, a modulus of about 13, and a hardness of 2.2. Openings (not shown) can be formed in the ILD 4 and filled with conductive materials to form metal plugs connecting devices and metal layers formed subsequently.

Among multiple layers of ILDs that may be formed subsequently, ILD 4 is the lowest and closest to the circuit devices. Therefore, it has significant effect on the device performance. Although curing has the benefit of lowering the k value and causing porous structures, it also introduces plasma-induced damage. The device performance such as gate leakage current is degraded. The mechanical strength is significantly affected. To minimize damage from curing, ILD 4 is not cured. Therefore, it has a slightly higher k and lower porosity than cured ILD. However, it has better mechanical property. Its underlying devices have lower leakage current.

The first metal layer (M1) 6 is formed on ILD 4. The M1 6 typically comprises metal lines and can be formed by first depositing a metal film, then using lithographic technology and reactive ion etching (RIE) to pattern the metal film. Known CVD techniques, such as PECVD, high-density plasma CVD (HDPCVD), atomic layer CVD (ALCVD) and low pressure CVD (LPCVD) can be used for depositing metal film. The M1 6 can also be formed by the well-known damascene process, which comprises steps of forming a trench in ILD 4, filling the trench with conductive materials such as copper or copper alloys, and performing a chemical mechanical polish (CMP) to level the surface. Since M1 6 is formed on or in ILD 4, ILD 4 is also referred to as M1 ILD 4. Upper ILD layers formed in subsequent processes will also be referred to by their corresponding metal layers.

An etch stop layer (ESL) 8 is formed on ILD 4 and M1 6, as also illustrated in FIG. 1. ESL 8 acts as an etch stop layer to protect underlying regions from being over etched. In the preferred embodiment, ESL 8 is formed by depositing a silicon nitride. In other embodiments, it may be formed using known materials such as oxynitride, aluminum oxide, aluminum nitride, titanium oxide, silicon carbide, and aluminum silicate etc. ESL is typically much thinner than ILD 4.

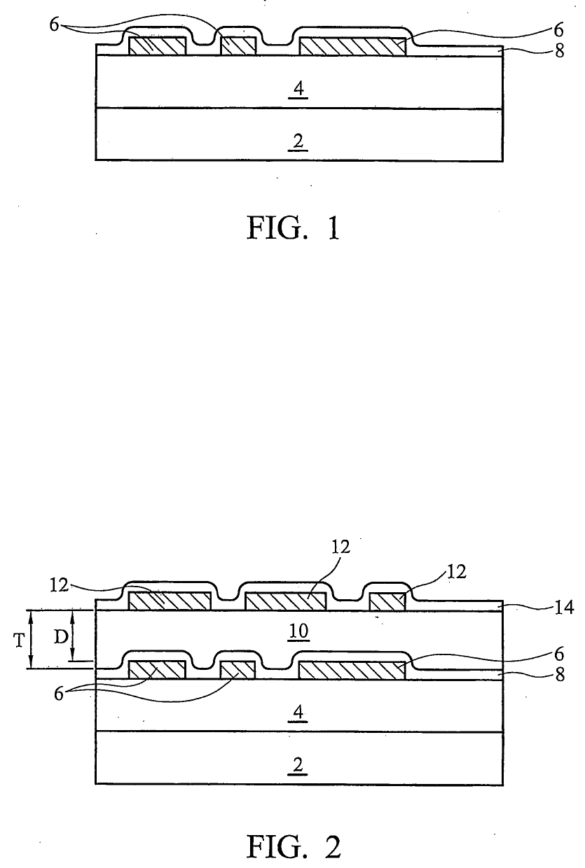

FIG. 2 illustrates formation of an ILD 10, a second metal layer (M2) 12 and an ESL 14. ILD 10 is formed on ESL 8. ILD 10 is also referred to as M2 ILD 10 since it has a metal layer (M2) in/on it. The formation of M2 ILD 10 and M2 12 is similar in part to the formation of M1 ILD 4 and M1 6. In the preferred embodiment, M2 ILD 10 is preferably formed by plasma enhanced CVD (PECVD), atomic layer deposition (ALD), sub-atmospheric CVD (SACVD), low pressure CVD (LPCVD), or other well-known deposition techniques. In an exemplary setting, an AMAT′ Producer is used as the depositing tool. Deposition is performed using precursors (CH₃)₃SiH (also known as 3MS or trimethylsilane) and oxygen and at a temperature of about 350° C.

Curing is then performed, preferably in a production tool that is also used for PECVD, HDPCVD, ALD, SACVD or LPCVD. It is also preferred that the curing is performed after deposition without removing the wafer out of the deposition equipment. In the preferred embodiment, plasma curing is performed in an environment containing hydrogen gas, and at a temperature of between about 200° C. and 450° C. Methods such as e-beam curing or ultra violet plasma curing can also be used.

In an embodiment where plasma curing is used, wafer is exposed to plasma. Plasma can be generated using mechanisms such as radio frequency (RF) and microwave electron cyclotron resonance (ECR). The exact conditions for the plasma curing depend upon what type of plasma is being used. An example of typical microwave plasma cure conditions is shown below.
Microwave plasma power: 500W-3000 W
Wafer temperature: 200° C.-500° C.
Process pressure: 1.0 Torr-4.0 Torr
Plasma cure time: <600 seconds
Plasma gases: H₂/O₂/CF₄
H₂ flow rate: >0-4000 sccm
O₂ flow rate: >0-4000 sccm
CF₄ flow rate: >0-400 sccm.

In an embodiment where UV curing is performed, an UV radiator tool is utilized, UV curing can occur at vacuum conditions, or at conditions without the presence of oxygen or oxidizing gases. An exemplary UV setting has parameters as following:
Temperature: 200-500° C.
Cure Time: <600 seconds
Process gases: Ar

Since the damage caused by UV curing is less severe than that of plasma curing, typically UV curing is more preferred than plasma curing in certain cases. However, e-beam curing is preferred for some others cases.

After curing, ILD 10 has a k value of less than about 2.5, a pore size of greater than about 10 Å and a hardness of greater than about 1.

When ILD 10 is cured, the property of M1 ILD 4 needs to be preserved, which means that ILD 4 should not be cured while ILD 10 is cured. Therefore, the curing depth D need to be controlled so that curing depth does not exceed the thickness T of ILD 10. One of the methods of controlling curing depth is adjusting the curing energy, such as the energy generating plasma, e-beam or ultra violet. The higher the curing energy is, the greater the curing depth is, and the lower the curing energy is, the smaller the curing depth is. The curing depth D is also related to the material of the ILD 10. A person skilled in the art will find out the relationship between the curing depth and curing energy through experiments. In an exemplary setting, ILD 10 is deposited by PECVD and has a thickness of about 500 nm to 600 nm by using e-beam curing in AMAT's Producer tool with a curing energy of about 2 kV to about 5 kV and at a temperature of about 200° C. to about 450° C. In such a setting, ILD 10 is cured without affecting ILD 4.

A second metal layer (M2) 12 is formed on ILD 10. ESL 14 is formed on ILD 10 and M2 12. The forming methods are similar to formation of M1 6 and ESL 8 with reference to FIG. 1 therefore will not be repeated.

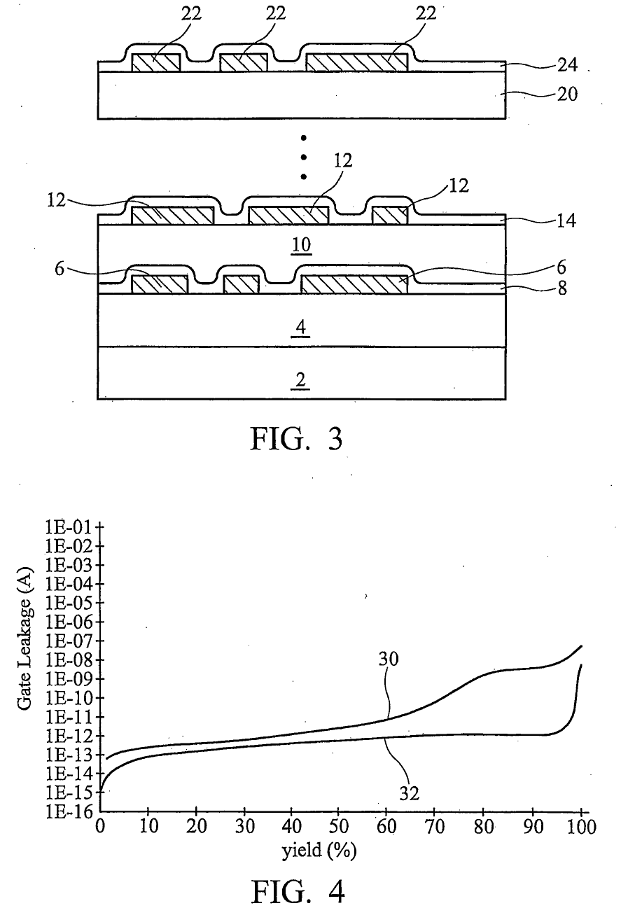

FIG. 3 illustrates formation of remaining ILDs and metal layers. The processes illustrated with reference to FIG. 2 are repeated and higher-level ILDs, metal layers, and ESLs are formed respectively for the upper metal layers. Preferably, for each subsequent ILD formation, curing is performed to lower the k value. Alternatively, an ILD can be cured after an ESL is formed on it.

In the preferred embodiment, the lowest level ILD 4 is not cured, thus it has higher hardness of greater than about 1.5 Gpa and higher k value of between about 2.5 and about 3.0. Its pore size is typically smaller than 10 Å. The higher levels of ILDs are cured, thus they have lower hardness of less than about 1.5 Gpa and lower k value of less than about 2.5. Cured dielectrics are more porous and have pore sizes typically greater than about 10 Å. In other embodiments, one or a few lowest level ILDs are not cured, and remaining upper level ILDs are cured. Since most of the ILDs are cured thus having lower k values, the overall parasitic capacitance is low, and device performance is not affected severely.

The combined scheme having cured and uncured ILDs (also referred to as “cured+uncured”) improves mechanical property and reduces the plasma damage to front-end-of-the-line (FEOL) devices. An exemplary result is shown in FIG. 4, where gate leakage current is illustrated as a function of yield, or cumulative probability, which indicates the probability of a device having a certain leakage current. A great number of devices are measured to generate the yield data. Line 30 shows the leakage current of devices with all ILDs cured (also referred as “cured+cured”). Line 32 shows the leakage current of devices with M1 ILD uncured and rest of the ILDs cured. It is noticed that the leakage current of line 32 is significantly lower than that of line 30. Therefore, by having “cured+uncured” scheme, the MOS devices' gate leakage current is improved significantly. The preferred embodiment has several advantage features. Plasma charge damage is reduced. The process if fully compatible with the current low-k/ultra low-k processes. There is no extra cost involved and existing tools can be used.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming semiconductor structures, the method comprising the steps of:
forming a first inter-layer dielectric (ILD);
forming a first metal layer over the first ILD;
forming a second ILD over the first metal layer;
forming a second metal layer over the second ILD; and
curing the second ILD.

2. The method of claim 1 wherein the first ILD has a k value of between about 2.5 and about 3.0, a pore size of smaller than about 10 Å, and a hardness of greater than about 1.5 Gpa.

3. The method of claim 1 wherein the second ILD has a k value of smaller than about 2.5, a pore size of greater than about 10 Å, and a hardness of smaller than about 1.5 Gpa.

4. The method of claim 1 further comprising:
forming a first etch stop layer (ESL) over the first ILD and the first metal layer; and
forming a second etch stop layer (ESL) over the second ILD and the second metal layer.

5. The method of claim 1 wherein the first ILD is formed by a method selected from the group consisting essentially of spin-on, chemical vapor deposition (CVD), plasma enhanced CVD (PECVD), atomic layer deposition (ALD), sub-atmospheric CVD (SACVD), and low pressure CVD (LPCVD).

6. The method of claim 1 wherein the second ILD is formed by a method selected from the group consisting essentially of spin-on, chemical vapor deposition (CVD), plasma enhanced CVD (PECVD), atomic layer deposition (ALD), sub-atmospheric CVD (SACVD), and low pressure CVD (LPCVD) and wherein a curing is performed to the second ILD.

7. The method of claim 6 wherein the second ILD is cured by a method selected from the group consisting of plasma curing, e-beam curing and ultra violet curing.

8. The method of claim 6 wherein the second ILD is cured by at a temperature of between about 200° C. and about 450° C.

9. The method of claim 1 further comprising:
forming a third ILD over the second metal layer;
forming a third metal layer over the third ILD; and
curing the third ILD.

10. A semiconductor structure comprising:
a first ILD over a substrate;
a first metal layer over the first ILD;
a cured second ILD over the first metal layer; and
a second metal layer over the second ILD.

11. The semiconductor structure of claim 9 wherein the first ILD has a k value of between about 2.5 and about 3.0, a pore size of smaller than about 10 Å, and a hardness of greater than about 1.5 Gpa.

12. The semiconductor structure of claim 9 wherein each of the second ILDs has a k value of smaller than about 2.5, a pore size of greater than about 10 Å, and a hardness of smaller than about 1.5 Gpa.

13. The semiconductor structure of claim 9 further comprising:
a first etch stop layer over the first ILD and the first metal layer; and
a second etch stop layer over the second ILD and the second metal layer.

14. The semiconductor structure of claim 9 further comprising a third ILD over the second ILD.

15. The semiconductor structure of claim 14 wherein the third ILD is cured.

16. The semiconductor structure of claim 14 wherein the third ILD is not cured.

17. A method of forming semiconductor structures, the method comprising the steps of:
forming a first uncured inter-layer dielectric (ILD) over a substrate;
forming a first metal layer over the first ILD;
forming at least one second ILD over the first ILD, each of the second ILD having one of second metal layer formed over; and
curing at least one of the second ILD.

18. The method of claim 16 wherein the first ILD has a k value of between about 2.5 and about 3.0, a pore size of smaller than about 10 Å, and a hardness of greater than about 1.5 Gpa.

19. The method of claim 16 wherein the second ILDs have k values of smaller than about 2.5, a pore sizes of greater than about 10 Å, and a hardness of smaller than about 1.5 Gpa.
